(19) United States
(12) Patent Application Publication
(10) Pub. No.: US 2015/0014715 A1
(43) Pub. Date: Jan. 15, 2015

(54) WHITE LIGHT LED MODULE STRUCTURE INCLUDING ULTRAVIOLET LIGHT

(71) Applicant: PROLIGHT OPTO TECHNOLOGY CORPORATION, Taoyuan County (TW)

(72) Inventors: CHEN-LUN HSING CHEN, TAOYUAN COUNTY (TW); JUNG-HAO HUNG, TAOYUAN COUNTY (TW); WEI-CHUN CHUANG, TAOYUAN COUNTY (TW)

(73) Assignee: PROLIGHT OPTO TECHNOLOGY CORPORATION, Taoyuan County (TW)

(21) Appl. No.: 13/966,674

(22) Filed: Aug. 14, 2013

(30) Foreign Application Priority Data
Jul. 12, 2013 (TW) 102125110

(51) Int. Cl. H01L 25/075

(52) U.S. Cl. CPC H01L 25/075
USPC 257/89

(57) ABSTRACT

A white light LED module structure including ultraviolet light comprises a white light LED module radiating a white light. An ultraviolet light LED chip is disposed in a packaging structure of the white light LED module. The ultraviolet light LED chip radiates an ultraviolet light. The white light and the ultraviolet light simultaneously illuminate an object. Alternatively, a white light LED module can be disposed for radiating a white light, and an ultraviolet light LED module can be disposed at one side of the white light LED module for radiating an ultraviolet light. The white light and the ultraviolet light simultaneously illuminate an object. The above-mentioned two methods allow an addition of an ultraviolet light wave band to the white light LED module, thereby activating fabrics containing fluorescent materials.

### BACKGROUND OF THE INVENTION

1. Field of the Invention

The present invention relates to a white light LED module structure, in particular to a white light LED module structure including ultraviolet light.

2. Description of the Related Art

In the past few years, high technology industry has sprung up. LED is one of the most competitive products of the optoelectronic industry in Taiwan. Further, LED is the most complete constructed item of the development of the optoelectronic industry recently in Taiwan. There are industries that go into the operation of the epitaxy of the upper reaches industries, the die of the middle reaches industries, and the packaging of the lower reaches industries. Among the industries, United Epitaxy Company Ltd. is the third enterprise that begins to manufacture a batch of high-illumination LED in the world. Taiwan has become the largest supply center of the lower reaches packaging products of the visible LED in the whole world. The high-illumination LED has already entered the world ranking, which enhances the global competitiveness greatly. The LED industry in Taiwan is ranked at the third place in the world, which is only after Japan and America. An industry structure of the die cutting, packaging and the application of the middle and lower reaches of the LED in Taiwan is complete, and the research and development and the production of the epitaxy of the upper reaches are rapidly growing, whereby Taiwan has potential for becoming the largest production country of the LED in the world.

The LED industry in Taiwan is presently in a production establishing period of the upper reaches industry structure of the single crystal and the epitaxy. The development of the LED industry is similar to the development of the IC industry. Further, the LED industry has an investing scope smaller than an investing scope of the IC wafer foundry, so the industry is established faster. Except for the present enterprises, such as United Epitaxy Company Ltd., TYNTEK Corporation, and EPISTAR Corporation, more than 10 enterprises have grown up during 2009-2010. Therefore, the production capacity will be tripled, and Taiwan will have an opportunity to be a global manufacture center of the high-illuminated epitaxy. Although the cost of the high-illumination LED manufactured by metal organic vapor phase epitaxy is more than the conventional illumination LED manufactured by vapor phase epitaxy and liquid phase epitaxy, the high-illumination LED has a high illumination and can be extensively applied. Moreover, the conventional illumination LED is stepping into a mature stage, so its growing range in the future is limited under the condition of the reducing demand and the increasing supply. On the other hand, the high-illumination LED is still in a growing stage and the new applications thereof are still unceasingly developed. Once the manufacture cost is decreased, the market application will be greatly increased.

Presently, the manufacture quantity of the high-illumination LED in the world is about 200 million pieces per month, and the manufacture quantity of the conventional illumination LED is about 4-5 billion pieces per month. The high-illumination LED applied to outdoor billboards, traffic signs, car lamps, and part of the backlights includes the advantages that the conventional illumination LED unable to attain. Further, the quad high-illumination die belongs to an oligopoly of the market form because it is only supplied by four enterprises in the world. Therefore, the factories have more power to decide the market price, in particular to United Epitaxy Company Ltd. that has a manufacture ability rising from the second place to the first place of the global ranking in 1998 and has a market share over 39%. A strategy that United Epitaxy Company Ltd. utilizes is to reduce the price difference between the high-illumination LED and the conventional LED by the price decline, and an object thereof is to gradually invade the enormous market commercial opportunity of the conventional LED. The high-illumination LED has a large developing scope in the future, and the key point thereof is that whether the high-illumination LED able to break the technique choke point and develop for a new application market. A white light is generated by an addition of the fluorescent powder to a blue light, which may cause a great stimulation of the LED application market. If the price could be reduced to a certain level, the white light LED will replace the conventional tungsten light bulb. Further, if the price falls gradually, the light sources, such as light bulbs and the fluorescent lights will be progressively replaced.

For the recent developing tendency of the LED products applied in the visible light products, the electric products are becoming lighter, thinner, shorter, and smaller, so the tendency of the LED products is also developed for becoming miniaturized, and the high-illumination products are the key point that the factories promotes. For the developing tendency of the LED products applied in the infrared light products, due to the popularization of the mobile communication, wireless transmission technique is regarded as a market with the highest potential. Further, the future developing key point of the LED industry in Taiwan will be the developing technique of the blue light LED. Both the promised large-sized billboard with full-colored LED and the LED that will change the history of illumination in the future require the blue light technique for developing the white light LED products. Therefore, whether the LED industry in Taiwan is able to break the current situation depends on how hard the factories work on the developing technique.

Although the LED light bulb that replaces the conventional tungsten light bulb has a lot of advantages, such as electric power saving, environmental protection, and high-illumination, some of the characteristics like UV light etc. of the conventional light bulb will not be existed in the LED light bulb. The general LED light cannot generate a fluorescent reflection corresponding to some special fabrics in darkness after installing the LED light bulb, whereby the products containing with fluorescent fabrics are unable to present their characteristic value of the fluorescent materials via the general LED light bulb.

Therefore, the inventor of the present invention discloses a white light LED module structure including ultraviolet light for improving the defects of the conventional technique. The present invention allows an ultraviolet light LED chip to be added in the white light LED module, so that a white light radiated from the white light LED module and an ultraviolet light radiated from the ultraviolet LED chip are able to simultaneously illuminate an object. Further, the LED module structure includes the ultraviolet light for activating the fluorescent materials of the object, so that the fluorescent materials are able to fluoresce. Therefore, the present invention contains a structure with novelty and inventive step.

### SUMMARY OF THE INVENTION

It is an object of the present invention to provide a white light LED module structure including ultraviolet light, so that the white light LED module is able to activate fabrics or other objects containing with fluorescent materials.

The present invention in conformity with the white light LED module structure including ultraviolet light comprising a white light LED module. At least one LED chip is disposed in a packaging structure of the white light LED module for radiating a white light. The packaging structure of the white light LED module preferably includes an ultraviolet light LED chip disposed at one side of the LED chip for radiating an ultraviolet light. The white light and the ultraviolet light simultaneously illuminate an object for activating fluorescent materials on the object to fluoresce.

It is a further object of the present invention to provide a LED module structure including ultraviolet light which comprises a white light LED module radiating a white light and an ultraviolet light LED module disposed at one side of the white light LED module for radiating an ultraviolet light. The white light and the ultraviolet light simultaneously illuminate an object for activating fluorescent materials on the object to fluoresce.

### BRIEF DESCRIPTION OF THE DRAWINGS

FIG. 1-A is a schematic view showing a packaging structure of a preferred embodiment of the present invention;

FIG. 1-B is a schematic view showing the packaging structure of the preferred embodiment of the present invention in radiation;

FIG. 2-A is a schematic view showing a packaging structure of a further preferred embodiment of the present invention;

FIG. 2-B is a schematic view showing the packaging structure of the further preferred embodiment of the present invention in radiation;

FIG. 3-A is a schematic view showing a packaging structure of a further preferred embodiment of the present invention; and

FIG. 3-B is a schematic view showing the packaging structure of the further preferred embodiment of the present invention in radiation

### DETAILED DESCRIPTION OF THE PREFERRED EMBODIMENTS

Before describing in detail, it should note that the like elements are denoted by the similar reference numerals throughout disclosure.

In order to improve the conventional LED of the LED packaging structure that does not include light capable of activating fluorescent materials on an object, the present invention utilizes a white light LED module combining with an ultraviolet LED chip for allowing the white light and the ultraviolet light to simultaneously illuminate the object. If the object has fluorescent materials, the ultraviolet light will activate the fluorescent materials to fluoresce. Therefore, the present invention provides with an invention with novelty and inventive step.

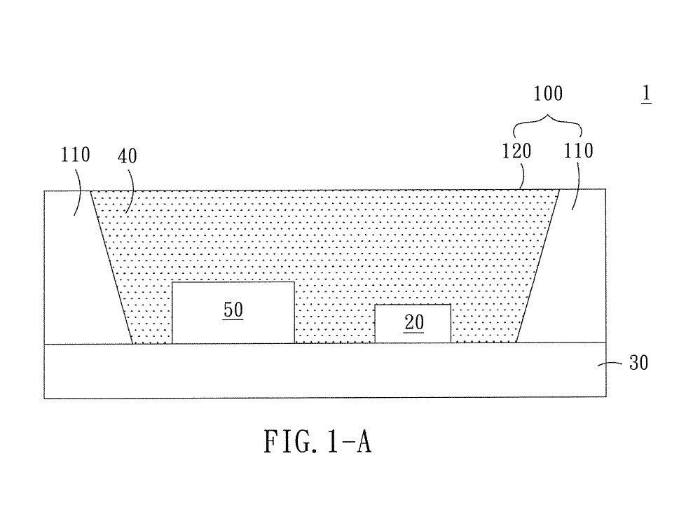

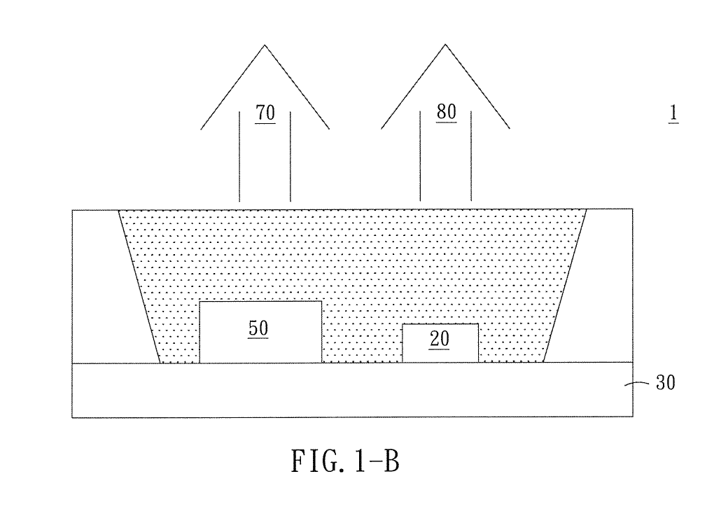

Referring to FIGS. 1-A and 2-A, a preferred embodiment of the present invention is shown. A LED module including ultraviolet light comprises a white light LED module 1 structure. The white light LED module 1 mainly includes a first frame 30 and a packaging structure 100 disposed on the first frame 30. The packaging structure 100 has a sleeve ring 110 and a packaging material 120. The sleeve ring 110 is preferably defined as a reflection unit and applied to fix the packaging material 120 around a LED chip or reflect a light of the LED chip. Herein, the sleeve ring 110 is disposed on the first frame 30 and annularly disposed on a LED chip 50. The packaging material 120 is adopted to fill a capacity room formed by the sleeve ring 110 and the first frame 30 and cover on the LED chip 50. The white light LED module 1 radiates a white light 70. Furthermore, an ultraviolet light LED chip 20 is preferably placed in the packaging structure 100 for being located at one side of the LED chip 50. The ultraviolet light LED chip 20 is disposed in the first frame 30 and the sleeve ring 110. The ultraviolet light LED chip 20 is covered by the packaging material 120 for radiating an ultraviolet light 80. The white light 70 and the ultraviolet light 80 simultaneously illuminate an object. If the object is a cloth or a good that contains fluorescent materials, the ultraviolet light will activate the fluorescent materials to fluoresce.

The present invention utilizes the white light LED module 1 to generate the white light 70. There are many kinds of methods for the white light LED module 1 to radiate the white light. For example, utilizing the RGB LED chip to mix the light for getting the white light; utilizing a blue light LED and yellow light fluorescent powder, so that the blue light of the blue light LED activates the yellow light fluorescent powder to generate the yellow light, and then mixing the light colors of the blue light and the yellow light for radiating a high-illuminated dichromatic white light; or using an ultraviolet light LED, red light fluorescent powder, green light fluorescent powder, and blue light fluorescent powder to render the ultraviolet light of the ultraviolet LED respectively activate the red light fluorescent powder, the green light fluorescent powder, and the blue light fluorescent powder so as to respectively generate a red light, a green light, and a blue light, and then mixing the light colors of the red light, the green light, and the blue light for radiating a high-illuminated trichromatic white light. Herein, the preferred embodiment is described by utilizing a blue light LED chip and yellow fluorescent powder, but the technique thereof for radiating the white light is not comprised in the present invention and herein is omitted. The packaging material 120 is added with fluorescent powder 40, so that the light generated from the LED chip 50 activates the light generated from the fluorescent powder 40, thereby using the principle of mixing and complementing to generate the white light 70.

Referring to FIG. 1-B, the fluorescent powder 40 is adopted to fill the capacity room formed by the sleeve ring 110 and the first frame 30 and cover a luminous route of the LED chip 50 and the ultraviolet light LED chip 20. The LED chip 50 radiates the white light 70 by activating and mixing the light of the fluorescent powder and the light of the LED chip 50. The ultraviolet light chip 20 radiates the ultraviolet light 80 directly. The ultraviolet light 80 does not and does not have to mix with the light for turning into the white light, but the ultraviolet light 80 is directly radiated from the white light LED module 1. The white light 70 is able to be directly illuminated on an object for illumination. The ultraviolet light 80 is applied to illuminate an object with fluorescent materials for activating the fluorescent materials of the objectto fluoresce. Further, the ultraviolet light 80 is adopted in the night, so that the object is able to radiate a recognizable fluorescence for attaining a special effect.

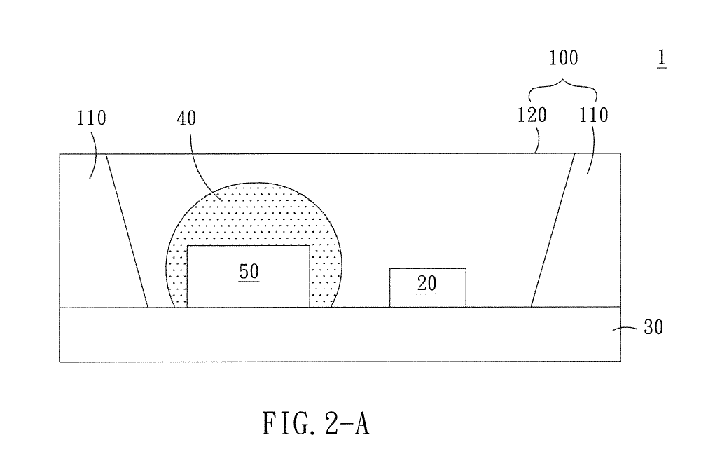

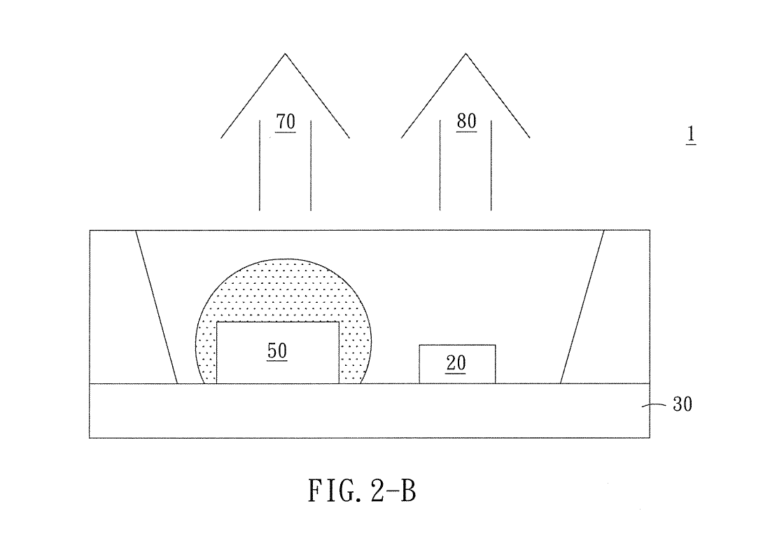

Referring to FIGS. 2-A and 2-B, a further preferred embodiment of the present invention is shown. The difference between this preferred embodiment and the above-mentioned preferred embodiment is that the fluorescent powder 40 covers a luminous route of the LED chip 50, but the fluorescent powder 40 does not cover a luminous route of the ultraviolet light LED chip 20. The LED chip 50 mixes with the light radiated from the LED chip 50 by activating the light generated from the fluorescent powder 40 for radiating the white light 70. The luminous route of the ultraviolet light LED chip 20 is not covered with the fluorescent powder 40, so that the ultraviolet light LED chip 20 radiates the ultraviolet light 80 directly and does not mix with the fluorescent powder 40, thereby enhancing the extraction efficiency of the ultraviolet light.

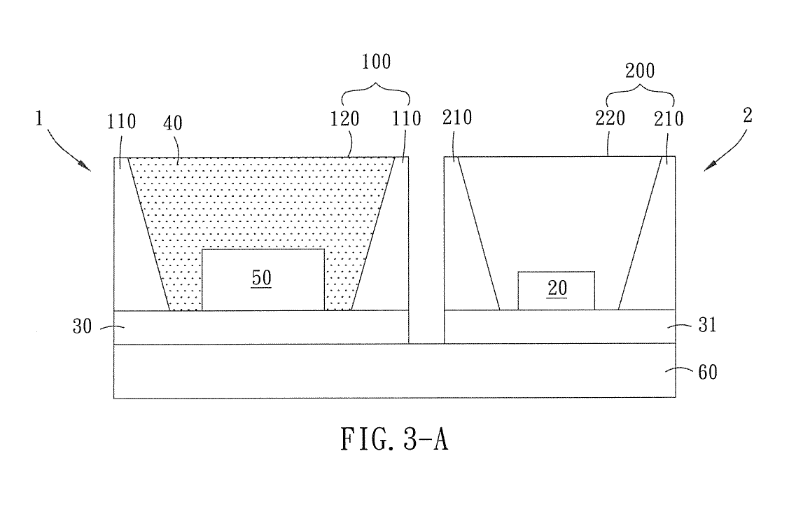

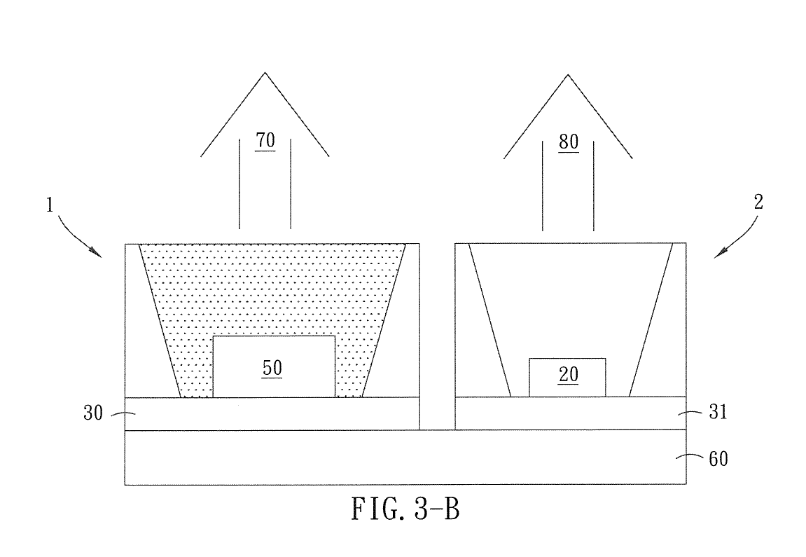

Referring to FIG. 3-A, a further preferred embodiment of the present invention is shown. The white light LED module structure including ultraviolet light comprises the white light LED module 1. The white light LED module 1 mainly includes the first frame 30 and the packaging structure 100. The packaging structure 100 has the sleeve ring 110 and the packaging material 120. The sleeve ring 110 is disposed on the first frame 30 and annularly disposed on the LED chip 50. The packaging material 120 is applied to fill in a capacity room formed by the sleeve ring 110 and the first frame 30 and cover on the LED chip 50 radiating the white light 70. An ultraviolet light LED module 2 is disposed at one side of the white light LED module 1. The ultraviolet light LED module 2 mainly comprises a second frame 31 and a packaging structure 200 disposed on the second frame 31. The packaging structure 200 includes a sleeve ring 210 and a packaging material 220. The sleeve ring 210 is disposed on the second frame 31 and annularly disposed on the ultraviolet light LED chip 20. The packaging material 220 is applied to fill a capacity room formed by the sleeve ring 210 and the second frame 31 and cover on the ultraviolet light LED chip 20 radiating the ultraviolet light 80. The first frame 30 of the white light LED module 1 and the second frame 31 of the ultraviolet LED module 2 are disposed on a substrate 60. The white light 70 and the ultraviolet light 80 simultaneously radiate the object. If the object is a cloth or a good that contains fluorescent materials, the ultraviolet light 80 will activate the fluorescent materials to fluoresce.

Referring to FIG. 3-B, the further preferred embodiment of the present invention is shown. The white light LED module structure including ultraviolet light utilizes the ultraviolet to directly illuminate cloths or goods with fluorescent materials for activating the fluorescent materials to fluoresce.

The packaging structure 100 of the white light Led module 1 includes the LED chip 50 and the ultraviolet light LED chip 20 disposed therein and electrically connected with each other on the first frame 30. The LED chip 50 and the ultraviolet light LED chip 20 of the present invention are not restricted to be electrically connected on the first frame 30 in series, in parallel, or in series-parallel combination. Further, the white light LED module 1 of the present invention is also not restricted to be electrically connected with the ultraviolet light LED module 2 on the substrate 60 in series, in parallel, or in series-parallel combination. The present invention can be attained by all of the above-mentioned methods. Moreover, a wave length of the LED chip 50 of the present invention ranges from 430 nm-480 nm. A wave length of the ultraviolet light LED chip 20 ranges from 300 nm-430 nm. A ratio of a radiant flux of the white light 70 of the LED chip 50 to a radiant flux of the ultraviolet light 80 of the ultraviolet LED chip 20 is 1˜50:1. The white light 70 and the ultraviolet light 80 interact in the scope of the ratio of the radiant flux for attaining a ratio of the best efficiency.

To sum up, the white light LED module structure including ultraviolet light makes use of a white light LED module 1 that radiates a white light 70. An ultraviolet LED chip 20 radiating an ultraviolet light 80 is disposed in a packaging structure of the white light LED module 1. The white light 70 and the ultraviolet light 80 simultaneously illuminate an object. A further structure of the present invention comprises the white light LED module 1 radiating the white light 70 and an ultraviolet light LED module 2 disposed at one side of the white light LED module 1 and radiating an ultraviolet light 80. The white light 70 and the ultraviolet light 80 simultaneously illuminate the object. The present invention utilizes the above-mentioned methods to render the white light 70 and the ultraviolet light 80 simultaneously illuminate an object. If the object is a cloth or a good that contains fluorescent materials, the ultraviolet light will activate the fluorescent materials of the object, thereby illuminating the illumination of the fluorescent materials.

While we have shown and described the embodiment in accordance with the present invention, it should be clear to those skilled in the art that further embodiments may be made without departing from the scope of the present invention.

What is claimed is:

1. A white light LED module structure including ultraviolet light comprising:
a white light LED module radiating a white light; wherein an ultraviolet light LED chip is disposed in a packaging structure of said white light LED module; said ultraviolet light LED chip radiating an ultraviolet light; said white light and said ultraviolet light simultaneously illuminating an object.

2. The white light LED module structure as claimed in claim 1, wherein said packaging structure includes a LED chip and fluorescent powder.

3. The white light LED module structure as claimed in claim 2, wherein said LED chip is electrically connected with said ultraviolet LED chip in parallel, in series or in a parallel-series combination.

4. The white light LED module structure as claimed in claim 2, wherein said fluorescent powder covers a luminous route of said LED chip, but said fluorescent powder does not cover a luminous route of said ultraviolet light LED chip.

5. The white light LED module structure as claimed in claim 2, wherein said fluorescent powder covers both luminous routes of said LED chip and said ultraviolet light LED chip.

6. The white light LED module structure as claimed in claim 2, wherein a wave length of said LED chip ranges from 430 nm to 480 nm.

7. The white light LED module structure as claimed in claim 1, wherein a wave length of said ultraviolet light LED chip ranges from 300 nm to 430 nm.

8. The white light LED module structure as claimed in claim 1, wherein a ratio of a radiant flux of said white light to a radiant flux of said ultraviolet light is 1˜50:1.

9. A white light LED module structure including ultraviolet light comprising:
a white light LED module radiating a white light; and
an ultraviolet LED module disposed at one side of said white light LED module for radiating an ultraviolet light; wherein said white light and said ultraviolet light simultaneously illuminate an object.

10. The white LED module structure as claimed in claim 9, wherein said white light LED chip is electrically connected with said ultraviolet LED chip in parallel, in series or in a parallel-series combination.

11. The white light LED module structure as claimed in claim 9, wherein said white light LED module includes a packaging structure, said packaging structure includes a LED chip and fluorescent powder disposed therein, and said fluorescent powder covers a luminous route of said LED chip.

12. The white light LED module structure as claimed in claim 11, wherein a wave length of said LED chip ranges from 430 nm to 480 nm.

13. The white light LED module structure as claimed in claim 9, wherein a wave length of said ultraviolet light LED chip ranges from 300 nm to 430 nm.

14. The white light LED module structure as claimed in claim 9, wherein a ratio of a radiant flux of said white light to a radiant flux of said ultraviolet light is 1˜50:1.
